(19) United States
(12) Patent Application Publication
(10) Pub. No.: US 2007/0064757 A1
(43) Pub. Date: Mar. 22, 2007

(54) Avalanche quantum intersubband transition semiconductor laser

(75) Inventors: Gyung Ock Kim, Seoul (KR); In Gyoo Kim, Daejeon (KR); Ki Joong Lee, Daejeon (KR); Cheol Kyun Lee, Daejeon (KR)

Correspondence Address: MAYER, BROWN, ROWE & MAW LLP, 1909 K STREET, N.W., WASHINGTON, DC, 20006, US

(73) Assignee: ELECTRONICS AND TELECOMMUNICATIONS RESEARCH INSTITUTE

(21) Appl. No.: 11/492,920

(22) Filed: Jul. 26, 2006

(30) Foreign Application Priority Data
Jul. 26, 2005 (KR) 2005-67857

(51) Int. Cl. H01S 5/00

(52) U.S. Cl. 372/43.01

(57) ABSTRACT

Provided is an avalanche quantum intersubband transition semiconductor laser. The laser includes: a first cladding layer, a first wave guide layer, an active region, a second wave guide layer, and a second cladding layer formed on a semiconductor substrate, wherein the active region consists of multiple stacks (periods) of a unit-cell structure, which is comprised of a carrier-multiplication layer structure for multiplying carriers, a carrier guide layer structure, and an QW active region to which carriers are injected, wherein intersubband optical radiative transitions of the carriers occur. Here, the carriers multiplied while passing though the carrier-multiplication layer structure, and injected into a optical transition level of the QW active region can achieve the high population inversion effectively, thereby high laser output power can be obtained with less stacked compact structure.

### CROSS-REFERENCE TO RELATED APPLICATION

This application claims priority to and the benefit of Korean Patent Application No. 2005-67857, filed Jul. 26, 2005, the disclosure of which is incorporated herein by reference in its entirety.

### BACKGROUND

1. Field of the Invention

The present invention relates to an quantum intersubband transition semiconductor laser, and more particularly, to an avalanche quantum intersubband transition semiconductor laser for providing high-power mid/far infrared rays with a compact structure.

2. Discussion of Related Art

A paper (Sov. Phys. Semiconductors, 5(4), pp. 707-709 (1971)) written by R. F. Kazarinov et al. predicts a possibility of amplification of an electromagnetic wave in a semiconductor superlattice structure. A paper (Appl. Phys. Lett. 55(7), pp. 654-656 (1989)) written by S. J. Borenstein et al., a paper (Appl. Phys. Lett. 59(23), pp. 2923-2925 (1991)) written by Q. Hu et al., a paper (Appl. Phys. Lett. 59(21), pp. 2636-2638 (1991)) written by A. Katalsky et al., and a paper (Appl. Phys. Lett. 63(8), pp. 1089-1091 (1993)) written by W. M. Yee et al. predict a possibility of a unipolar quantum intersubband transition quantum well semiconductor light amplification by stimulated emission of radiation (LASER).

As such, specialists in the field are paying attention to an advantage obtained from several types of unipolar quantum intersubband transition semiconductor lasers. For example, it includes a frequency characteristic not limited by recombination of electrons and holes of an energy bang gap, a narrow line width resulting from theoretical non-existence of a line width increase factor, a lower temperature dependence of the lasing threshold than that of a conventional bipolar semiconductor laser, and the like.

If the unipolar quantum intersubband transition semiconductor laser is appropriately designed, it can emit light at wavelengths of a mid-infrared (IR) to a sub-millimeter spectrum region. For example, by a carrier optical transition between quantum well (QW) confined levels, the light can be emitted at wavelengths of about 3 to more than 100 microns. The wavelength of the emitted light can be designed on the basis of the same heterostructure over a wide spectrum range. This wavelength band cannot be obtained with a conventional semiconductor laser diode.

Further, since the unipolar quantum intersubband transition semiconductor laser can be fabricated on the basis of a III-V compound semiconductor material system (for example, a hetero structure based on GaAs, InP, and the like), which has a relatively large energy band gap and has been sufficiently developed in technology, it does not need to use a small energy band gap material susceptible to temperature and complicated in process, such as PbSnTe.

Conventional technology for realizing the unipolar quantum intersubband transition semiconductor laser includes a typical resonant tunneling structure based on a multiple quantum well structure. For example, a paper (“Carrier transport and intersubband population inversion in couple quantum well”, Appl. Phys. Lett. 63(8), pp. 1089-1091 (1993)) written by W. M. Yee et al. provides two kinds of coupled quantum well structures. The coupled quantum well structures include an emission quantum well sandwiched between energy filter wells, respectively. The quantum well structure is sandwiched between n-doped injector and collector regions.

In 1994, Faist, Capasso et al. designated and fabricated the unipolar quantum intersubband transition semiconductor laser called as a quantum cascade laser, which first emits light at a wavelength of about 4.2 microns on the basis of a GaInAs/AlInAs material system. The quantum cascade laser can be also realized using other material systems, and easily designed for lasing at a wavelength selected from the wide spectrum.

The quantum cascade laser includes a semiconductor quantum well(QW) active region with multi layers to be a light-emitting region, and this QW active region is separated from an adjacent active region by energy relaxation regions (carrier injectors). For example, it can be designed that a vertical transition occurring within the same quantum well or a diagonal transition between quantum confined energy levels of adjacent quantum wells is selected as an light emitting optical transition between confined energy states in the QW active region.

A unipolar quantum intersubband transition laser diode of the mid- to far IR wavelength band can be used in wide fields such as pollution monitoring, process control, and car. In particular, the quantum cascade semiconductor laser capable of emitting mid-infrared is attracting much attention in commercial and scholastic aspects.

However, the conventional quantum cascade laser is constructed such that one electron passes through N stacks (periods) of a basic unit cell structure, consisting of a QW active region and energy relaxation region, while emitting N photons. In order to obtain sufficient optical power, ˜25 to 70 or more stacks (periods) of the basic unit cell structure should be formed. Accordingly, since the complicated multi layer should be epitaxially grown by a molecular beam epitaxy (MBE), the conventional quantum cascade laser is very difficult in manufacture and therefore, is restrictively researched and developed, as a state of the art technology.

### SUMMARY OF THE INVENTION

The present invention is directed to implementation of an quantum intersubband transition semiconductor laser which is easy to manufacture owing to a simple compact structure consisting of a fewer number of stacks (periods).

The present invention is also directed to implementation of an quantum intersubband transition semiconductor laser that is capable of obtaining high power by injecting a plurality of carriers, multiplied while passing through a PIN-type or PN-type carrier-multiplication layer structure, into an upper transition level of a QW active region to achieve a high population inversion between the light emitting transition states.

One aspect of the present invention is to provide an quantum intersubband transition semiconductor laser including: a first cladding layer, an active region, and a second cladding layer formed on a semiconductor substrate, wherein the active region is comprised of N periods of unit cell structure, wherein the unit cell structure consists of a PIN-type carrier-multiplication layer structure for multiplying carriers, a carrier guide layer, such as a funnel injector, for relaxing energy of the carrier and injecting the carrier into an QW active region, and an QW active region to which carriers are injected and then undergo optical transitions.

Another aspect of the present invention is to provide an quantum intersubband transition semiconductor laser including: a first cladding layer, an active region, and a second cladding layer formed on a semiconductor substrate, wherein the active region is comprised of N periods (stacks) of unit cell structure, wherein the unit cell structure is comprised of a combination of a carrier-multiplication layer structure for multiplying carriers, a carrier guide layer, such as a funnel injector, for relaxing energy of the carrier and injecting the carrier into an QW active region, and the QW active region to which the carrier is injected, where optical transition occurs.

Yet another aspect of the present invention is to provide an quantum intersubband transition semiconductor laser including: a first cladding layer, an active region, and a second cladding layer formed on a semiconductor substrate, wherein the active region is comprised of N periods (stacks) of unit cell structure, wherein the unit cell structure is comprised of a carrier-multiplication layer structure for multiplying carriers, a carrier guide layer structure for relaxing energy of the carrier and injecting carriers into a QW active region, a QW active region to which the carrier is injected, thereby an optical transition occurs, and a carrier energy relaxation layer.

The laser may further include: the semiconductor substrate; a first cladding layer, a first wave guide layer formed between the first cladding layer and the active region; a second wave guide layer formed between the active region and the second cladding layer.

A combination of the carrier-multiplication layer structure and the QW active region may be repeatedly stacked, the combination of the carrier-multiplication layer structure, the carrier guide layer, and the QW active region may be repeatedly stacked, or the combination of the carrier-multiplication layer structure, the carrier guide layer, the QW active region, and the carrier energy relaxation layer may be repeatedly stacked.

The carrier guide layer, the QW active region, and the energy relaxation layer may have a multiple quantum well structure or superlattice structure.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a cross-sectional view of an avalanche quantum intersubband transition semiconductor laser according to an exemplary embodiment of the present invention; and

FIGS. 2 to 4 are conduction-band energy diagrams of avalanche quantum intersubband transition semiconductor lasers according to exemplary embodiments of the present invention.

### DETAILED DESCRIPTION OF PREFERRED EMBODIMENTS

Since a conventional mid/far infrared quantum cascade laser has a structure where one electron passes through N stacks (periods) of unit-cell structure while emitting N photons, it needs stacks (periods) of 25 to 70 or more in number so as to obtain sufficient optical power. Accordingly, the structure is complicated, difficult in growing a quantum cascade laser structure.

The present invention forms a carrier-multiplication layer structure including PIN type layers for generating carrier multiplication between QW active regions in which an intersubband radiative transition occurs, and a carrier guide layer structure structure for relaxing energies of multiplied carriers and injecting multiplied carriers into an upper transition level of an adjacent QW active region. The present invention enhances efficiency of carrier injection into the QW active region to achieve high population inversion, thereby obtaining high power even with a simple compact stacks (periods) and therefore, facilitating manufacture.

Hereinafter, an exemplary embodiment of the present invention will be described in detail. However, the present invention is not limited to the embodiments disclosed below, but can be implemented in various types. Therefore, the present embodiment is provided for complete disclosure of the present invention and to fully inform the scope of the present invention to those ordinarily skilled in the art.

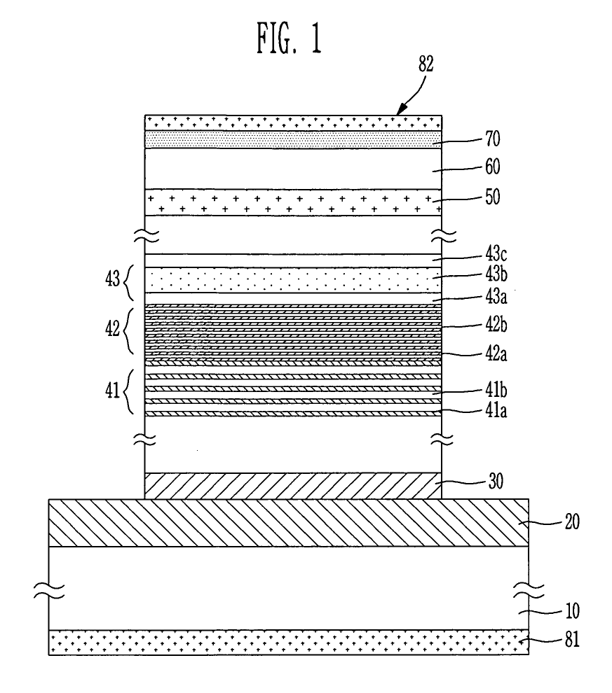

FIG. 1 is a cross-sectional view of an quantum intersubband transition semiconductor laser according to an exemplary embodiment of the present invention.

A lower cladding layer 20 and a wave guide layer 30 are formed on a semiconductor substrate 10 made of InP. Here, the lower cladding layer 20 is made of InP to the thickness of 1 microns and below and the wave guide layer 30 is made of InGaAs to the thickness of 1 microns and below. The unit cell structure which is consisted of A QW active region 41 of InGaAs/InAlAs, a carrier guide layer structure 42 of InAlAs/InAlGaAs, and a carrier-multiplication layer structure 43 are formed on the wave guide layer 30. The unit cell structure, that is, the combination of the QW active region 41, the carrier guide layer structure 42, and the carrier-multiplication layer structure 43 can be repeatedly stacked two or more times, preferably, two to ten times.

The QW active region 41 can be formed to have an undoped InGaAs/InAlAs multiple quantum well structure or superlattice structure based on the design of emitting light wavelength. It can be formed to have the multiple quantum well structure, and stacks (periods) of a InGaAs quantum well layer 41a and a InAlAs quantum barrier layer 41b as shown in FIG. 1. In other words, a vertical transition quantum well structure or a diagonal transition quantum well structure can be applied, and one, two, three, four-quantum well structure, or a multiple quantum well structure can be applied.

QW active region(41) can be formed to have a InGaAs/InAlAs multiple quantum well structure or a InGaAs/InAlAs superlattice structure. In other words, as shown in FIG. 1, the carrier guide layer structure 42 can be formed to have a stacks of a InGaAs quantum well layer 42a and a InAlAs quantum barrier layer 42b.

The carrier-multiplication layer structure 43 is comprised of an n-type doped layer 43a, a undoped multiplication layer 43b, and a p-type charge layer 43c. The n-type doped layer 43a is formed of n-InGaAs or n-InAlAs to have a small thickness of 500 Å. In operation, the multiplication layer 43b allows an electric field having an intensity greater than ˜10⁵V/cm to be applied, and is formed of undoped InGaAs or InAlAs to have a thickness of 1500 Å and below, for moderate avalanche multiplication of carriers. The p-charge layer 43c is formed of p-InGaAs or p-InAlaAs to have a small thickness of 500 Å and below.

A wave guide layer 50 and a cladding layer 60 are formed on the above structure. Here, the cladding layer 60 is formed of InP to have a thickness of 1 microns and below, and the wave guide layer 50 is formed of InGaAs to have a thickness of 1 microns and below. Electrodes 81 and 82 are formed on a bottom surface of the substrate 10 and above the cladding layer 60, respectively. In order to enhance ohmic contact characteristics between the electrode 82 and the cladding layer 60, an emitter contact layer 70 can be formed of a conductive material, for example, n⁺-InGaAs to have a thickness of several thousands Å between the electrode 82 and the cladding layer 60.

In other words, the cladding layer 20 and the wave guide layer 30 are formed on the semiconductor substrate 10, and the QW active region 41carrier guide layer structure(42) and the carrier-multiplication layer structure 43 are formed on the wave guide layer 30. At this time, the unit cell structure, that is, the combination of the QW active region 41, the carrierguide(42) layer structure and the carrier-multiplication layer structure 43 can be repeatedly stacked two or more times, preferably, two to ten times on the wave guide layer 30.

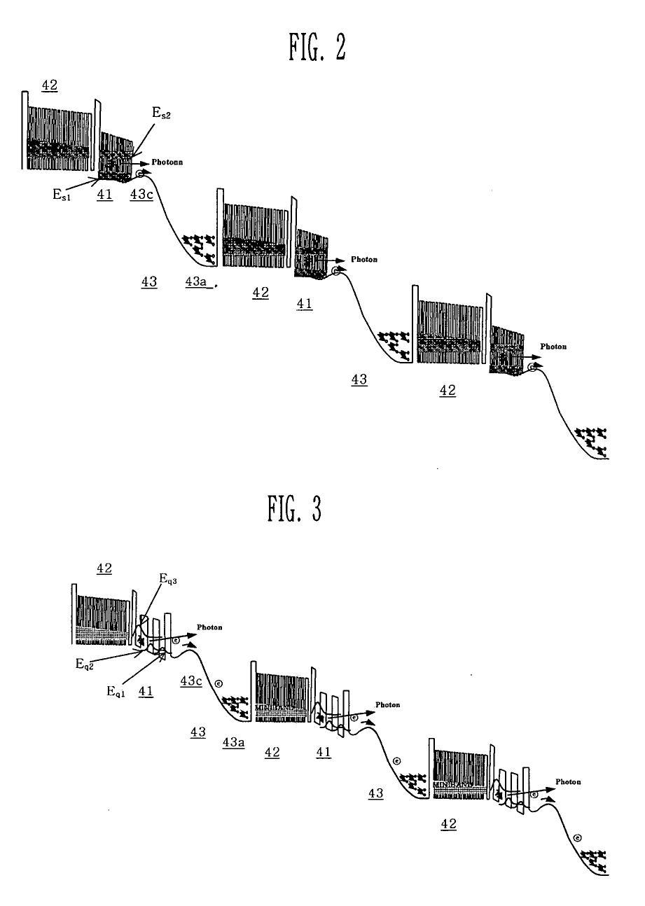

Operation of the inventive above-constructed quantum intersubband transition semiconductor laser will now be described with reference to FIGS. 2 to 4.

The inventive quantum intersubband transition semiconductor laser includes laser includes the unit cell structure which is consisted of the carrier-multiplication layer structure 43 having the multiplication layer 43b between the QW active regions 41 where optical transition occurs, and the carrier guide layer structure 42 for guiding the multiplied carriers to be injected into the upper transition level of the adjacent QW active region 41. Accordingly, carriers injected into the upper transition level increase in number and as a result, injection efficiency increases, thereby achieving high population inversion between optical transition quantum confined levels of the QW active region 41 and results in the high-power quantum intersubband transition laser.

When a voltage is applied to the electrodes 81 and 82, the carriers pass through the carrier-multiplication layer structure 43 while increasing in number by carrier multiplication, caused by impact ionization in the relatively thin multiplication layer 43b having a thickness of 1500 Å and below that is, by moderate avalanche multiplication,

The carriers multiplied in the multiplication layer 43b are guided by the carrier guide layer structure 42 and injected into the transition level of the adjacent QW active region 41, thereby relaxing the energies into the injection energy level to the QW active region. In other words, the carrier guide layer structure 42 guides the multiplied and widely energy-distributed carriers to have a narrow energy distribution, and relaxes the energies of the carriers to inject the carriers to the QW active region 41. The carriers subjected to quantum intersubband transition in the QW active region 41 sequentially pass through the next neighboring carrier-multiplication layer structure 43 and are again multiplied. By such consecutive multiplication of carriers, a large gain of optical power can be obtained with less repeated structure of unit cells, compared with the conventional quantum cascade laser structure.

For example, assuming that the unit cell structure, that is, the combination of the QW active region 41, the carrier guide layer structure 42, and the carrier-multiplication layer structure 43 is repeatedly stacked N times and the carriers are multiplied “m” times in one multiplication layer, the injected one carrier can be multiplied into m^{N} and as a result, photons of m^{N} can also be created.

Accordingly, in comparison to a conventional quantum cascade laser (QCL) where one electron passes through N cascade stacks (periods) while creating N photons, the inventive avalanche quantum intersubband transition semiconductor laser has an advantage in that the high power can be obtained with the simple compact structure. In particular, a multiplication layer structure having a small thickness may be applied, thereby enhancing gain, speed, and stability.

An emitting light wavelength of the above-constructed quantum intersubband transition semiconductor laser is determined by confined energy levels of the quantum well structure corresponding to the optical transition levels of the QW active region 41.

FIG. 2 is a conduction-band energy diagram of the avalanche quantum intersubband transition semiconductor laser according to an embodiment of the present invention.

The avalanche quantum intersubband transition semiconductor laser includes the unit cell structure which is consisted of the QW active region 41, the carrier guide layer structure 42, and the carrier-multiplication layer structure 43. In this case, the QW active region 41 has a superlattice structure, and the carrier guide layer structure 42 has a multiple quantum well or superlattice structure.

Referring to FIG. 2, multiplied electrons under applied voltage are guided by the carrier guide layer structure 42 and injected into an Eₛ₂ subband formed in the adjacent QW active region 41 having the superlattice structure. Here, the population inversion between the Eₛ₂ subband and the Eₛ₁ subband causes a radiative optical transition, thereby emitting a plurality of photons, and the electrons transitioned to the Eₛ₁ subband having low energy again sequentially pass through the next adjacent carrier-multiplication layer structure 43 and are multiplied. In other words, the carrier guide layer structure 42 guides the multiplied and widely energy-distributed electrons to have a narrow energy distribution, and relaxes energies of electrons to inject the electrons into the Eₛ₂ subband of the next neighboring QW active region 41. The carriers again subjected to the quantum intersubband transition in the QW active region 41 again sequentially pass through the next neighboring carrier-multiplication layer structure 43 and are again multiplied, and pass through the carrier guide layer structure 42 and the QW active region 41, thereby obtaining a large gain of optical power through such sequential multiplication of carriers. That is, assuming that the unit cell structure, that is, the combination of the QW active region 41, the carrier guide layer structure 42, and the carrier-multiplication layer structure 43 is repeatedly stacked N times and the carriers are multiplied “m” times as much in one multiplication layer, as a resultant effect, the injected one carrier can be multiplied into m^{N}, and photons of m^{N} can also be created.

FIG. 3 is a conduction-band energy diagram of the quantum intersubband transition semiconductor laser according to an embodiment of the present invention.

The quantum intersubband transition semiconductor laser includes the unit cell structure which is consisted of the QW active region 41, the carrier guide layer structure 42, and the carrier-multiplication layer structure 43. In this case, the QW active region 41 has a three-quantum well structure.

Referring to FIG. 3, electrons input in applying the voltage are guided by the carrier guide layer structure 42 and injected into an E_{q3} subband formed in the adjacent QW active region 41 having a three-quantum well structure. Here, the population inversion between the E_{q3} subband and the E_{q2} subband causes a laser transition, thereby emitting a plurality of photons, and the electrons transitioned to the E_{q2} subband having low energy are quickly relaxed to an E_{q1} subband having lower energy, thereby enhancing a population inversion effect between the E_{q3} subband and the E_{q2} subband. The electrons relaxed to the E_{q1} subband again sequentially pass through the next adjacent carrier-multiplication layer structure 43 and are multiplied. In other words, the carrier guide layer structure 42 guides the multiplied and widely energy-distributed electrons to have a narrow energy distribution, and relaxes energies of the electrons to inject the electrons to the E_{q3} subband of the next neighboring the QW active region 41. The carriers again subjected to the quantum intersubband transition in the QW active region 41 again sequentially pass through the next neighboring carrier-multiplication layer structure 43 and are again multiplied, and pass through the carrier guide layer structure 42 and the active region 41, thereby obtaining a very great gain of optical power by such continuous multiplication of the carriers. That is, assuming that the unit cell structure, that is, the combination of the QW active region 41, the carrier guide layer structure 42, and the carrier-multiplication layer structure 43 is repeatedly stacked N times, and the carriers are multiplied “m” times as much in one multiplication layer, as a resultant effect, the injected one carrier can be multiplied into m^{N} and the photons of m^{N} can also be created.

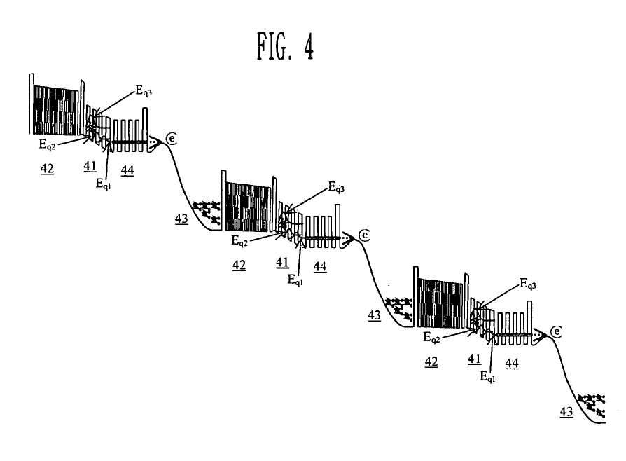

FIG. 4 is a conduction-band energy diagram of the quantum intersubband transition semiconductor laser according to an embodiment of the present invention.

Referring to FIG. 4, in this structure, the unit cell structure includes an energy relaxation layer 44 that is inserted as a carrier relaxation region between the QW active region 41 and the carrier-multiplication layer structure 43. Electrons under the applied voltage are guided by the carrier guide layer structure 42 and injected into an E_{q3} subband formed in the adjacent QW active region 41 having a three-quantum well structure. Here, the population inversion between the E_{q3} subband and the E_{q2} subband causes a laser transition, thereby emitting a plurality of photons, and the electrons transitioned to the E_{q2} subband having low energy are relaxed to an E_{q1} subband having lower energy, and the electrons transitioned to the E_{q1} subband are sequentially easily relaxed to the energy relaxation layer 44, thereby enhancing a population inversion effect between the E_{q3} subband and the E_{q2} subband, and preventing dopants of the carrier-multiplication layer structure 43 from being diffused into the QW adjacent active region 41.

As described above, according to the present invention, the carrier multiplication, that is, a plurality of carriers multiplied while passing though the carrier-multiplication layer structure are injected into a optical transition level of the QW active region to achieve the high population inversion, thereby obtaining high output power. Further, the conventional quantum cascade laser should employ a large number of periods(stacks) of multiple quantum well structures in order to obtain the sufficient optical power and therefore its manufacture is difficult, but the inventive semiconductor laser is easy to manufacture owing to its simple compact structure, that is, the fewer-number stacks (periods) structure. Accordingly, the mid/far infrared quantum intersubband transition semiconductor laser having high power with low cost can be implemented.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. An Avalanche quantum intersubband transition semiconductor laser comprising:
a first cladding layer, an active region, and a second cladding layer formed on a semiconductor substrate,
wherein the active region includes a unit cell structure comprised of a carrier-multiplication layer structure for multiplying carriers, a carrier guide layer structure, and an QW active region to which carriers are injected, wherein the carriers undergo intersubband optical radiative transitions.

2. The Avalanche quantum intersubband transition semiconductor laser according to claim 1, wherein the unit cell structure comprised of a combination of the carrier-multiplication layer structure, a carrier guide layer structure, and the QW active region is repeatedly stacked.

3. The Avalanche quantum intersubband transition semiconductor laser according to claim 1, wherein the carrier guide layer structure has a multiple quantum well or superlattice structure.

4. The Avalanche quantum intersubband transition semiconductor laser according to claim 1, wherein the QW active region has a multiple quantum well or superlattice structure.

5. The Avalanche quantum intersubband transition semiconductor laser according to claim 1, wherein the carrier-multiplication layer structure is comprised of a p-charge layer, a multiplication layer for multiplying the carrier, and an n-type doped layer.

6. The quantum intersubband transition semiconductor laser according to claim 1, further comprising:
a first wave guide layer formed between the first cladding layer and the QW active region;
a second wave guide layer formed between the QW active region and the second cladding layer.

7. The Avalanche quantum intersubband transition semiconductor laser according to claim 1, wherein a multiplication layer of the carrier-multiplication layer structure is comprised of a semiconductor superlattice structure.

8. A quantum intersubband transition semiconductor laser comprising:
a first cladding layer, an active region, and a second cladding layer formed on a semiconductor substrate,
wherein the active region is comprised of a combination of a carrier-multiplication layer structure for multiplying carriers, and the QW active region to which the carriers are injected, wherein the carriers undergo intersubband optical radiative transitions.

9. The Avalanche quantum intersubband transition semiconductor laser according to claim 8, wherein the combination of the carrier-multiplication layer structure and the QW active region is repeatedly stacked.

10. The Avalanche quantum intersubband transition semiconductor laser according to claim 8, wherein the QW active region has a multiple quantum well or superlattice structure.

11. The Avalanche quantum intersubband transition semiconductor laser according to-claim 8, wherein the carrier-multiplication layer structure is comprised of a p-charge layer, a multiplication layer for multiplying the carrier, and an n-type doped layer.

12. The quantum intersubband transition semiconductor laser according to claim 8, further comprising:
a first wave guide layer formed between the first cladding layer and the QW active region;
a second wave guide layer formed between the QW active region and the second cladding layer.

13. The Avalanche quantum intersubband transition semiconductor laser according to claim 8, wherein a multiplication layer of the carrier-multiplication layer structure is comprised of a semiconductor superlattice structure.

14. An Avalanche quantum intersubband transition semiconductor laser comprising:
a first cladding layer, an active region, and a second cladding layer formed on a semiconductor substrate,
wherein the active region is comprised of a combination of a carrier-multiplication layer structure for multiplying carriers, a carrier guide layer structure for relaxing energies of carriers to the injection energy level and injecting the carrier into an QW active region, the QW active region to which the carrier are injected, wherein the carriers undergo intersubband optical radiative transitions, and a carrier energy relaxation layer.

15. The Avalanche quantum intersubband transition semiconductor laser according to claim 14, wherein the combination of the carrier-multiplication layer structure, the carrier guide layer structure, the QW active region, and the carrier energy relaxation layer is repeatedly stacked.

16. The Avalanche quantum intersubband transition semiconductor laser according to claim 14, wherein the energy relaxation layer has a multiple quantum well or superlattice structure.

17. The Avalanche quantum intersubband transition semiconductor laser according to claim 14, wherein the carrier guide layer structure has a multiple quantum well or superlattice structure.

18. The Avalanche quantum intersubband transition semiconductor laser according to claim 14, wherein the QW active region has a multiple quantum well or superlattice structure.

19. The Avalanche quantum intersubband transition semiconductor laser according to claim 14, wherein the carrier-multiplication layer structure is comprised of a p-charge layer, a multiplication layer for multiplying the carrier, and an n-type doped layer.

20. The quantum intersubband transition semiconductor laser according to claim 14, further comprising:
a first wave guide layer formed between the first cladding layer and the QW active region;
a second wave guide layer formed between the QW active region and the second cladding layer.

21. The Avalanche quantum intersubband transition semiconductor laser according to claim 14, wherein a multiplication layer of the carrier-multiplication layer structure is comprised of a semiconductor superlattice structure.
